(19) United States
(12) Patent Application Publication
(10) Pub. No.: US 2003/0201763 A1
(43) Pub. Date: Oct. 30, 2003

(54) Battery gauge

(76) Inventor: Kaiyou Fang, Sparks, NV (US)

Correspondence Address: Brian C. Kelly, Hawkins, Folsom & Muir, Suite 416, One East Liberty St., Reno, NV, 89501, US

(21) Appl. No.: 10/137,938

(22) Filed: Apr. 30, 2002

(51) Int. Cl. G01R 31/02

(52) U.S. Cl. 324/72

(57) ABSTRACT

A battery voltage meter for reading the voltage of a car battery or the alternator output by tapping the power grid of the car through the cigarette lighter. In an alternate embodiment the device includes an air pressure gauge for measuring the tires in the same compact housing.

### BACKGROUND

1. Field of Invention

This invention relates generally to the field of Battery gauges for measuring the charge in an automobile battery.

2. Description of the Prior Art

The prior art includes many battery gauges which attach to the terminals of the battery. There have been numerous safety issues with the battery under the hood of the car. The applicants invention overcomes the safety shortcomings of the prior art by eliminating the need to open the hood while providing a highly accurate reading of the state of the battery's charge.

### SUMMARY & OBJECTS OF THE INVENTION

A first object of the invention is to provide a device for measuring the battery charge without opening the hood of a car.

A second object of the invention is to provide a battery meter that is substantially universal in application to different cars.

### BRIEF DESCRIPTION OF DRAWINGS

FIG. 1 is a front view of the meter.

FIG. 2 is a front view of an alternate embodiment of the meter.

FIG. 3 is a back view of the meter.

FIG. 4 is a side view of the meter.

FIG. 5 is a end view of the meter.

### DESCRIPTION OF PREFERRED EMBODIMENT

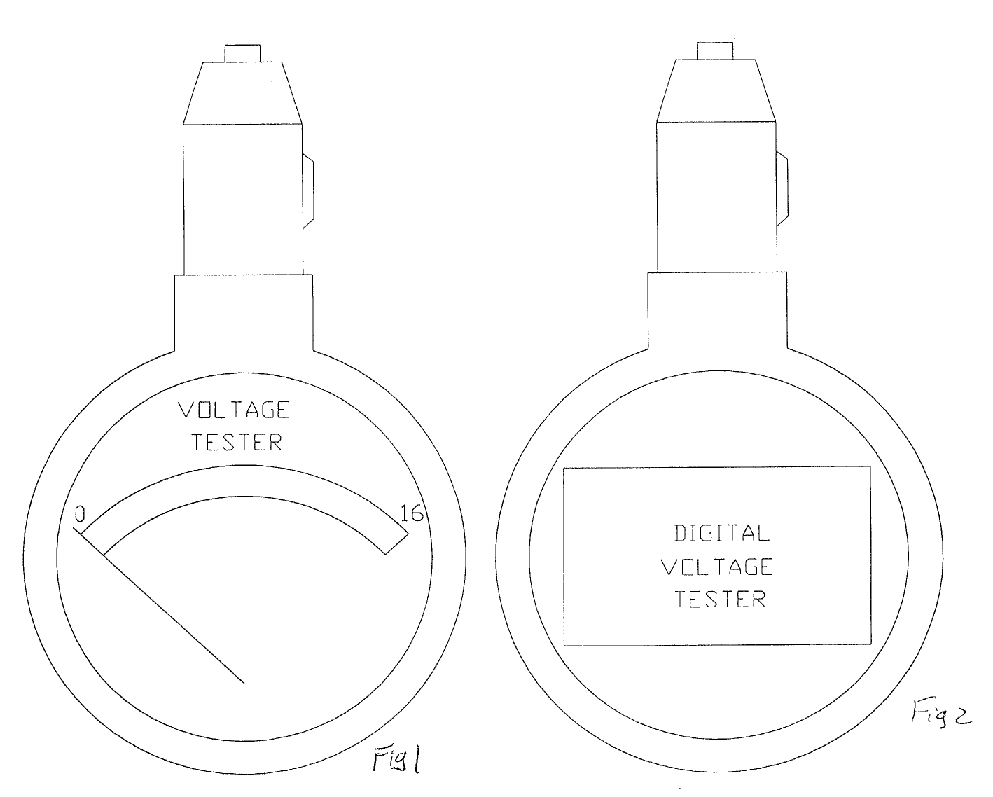

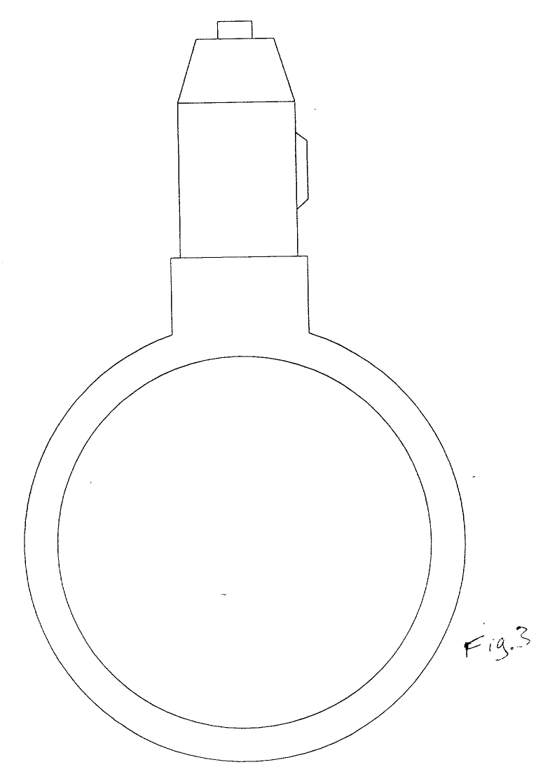

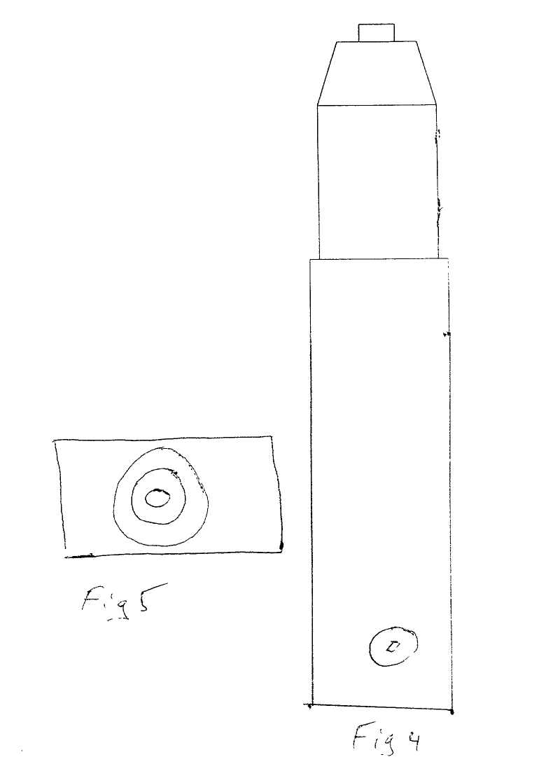

The meter 1 is shown in FIG. 1. The extension 2 is sized to fit the cigarette lighter. The extension further includes contacts on its terminus and side to contact the contacts on the end and side of the cigarette lighter. FIG. 2 shows another embodiment with a digital read out 3. FIGS. 3-5 show the simple structure of the device. It is contemplated that the housing 4 will be made in durable plastic or metal. Though plastic may be preferable to prevent shock to the operator.

The invention is a safe method to determine the battery's voltage available without having to open the hood. There are situations where opening the hood is inconvenient or simply dangerous. When a car is stalled on the road, rather than getting out in traffic; it would be safert to use the invention to evaluate the battery from the interior. Batteries commonly fail in cold weather. There is a distinct likelihood that the hood may have ice and snow thereon which may even prevent opening the hood. Finally evaluating the effectiveness of an alternator often requires the motor to be running there are a number of hot spots and moving parts that can be avoided entirely by using the invention.

Presently, alternator testing requires two operators. One must monitor the Idle and keep it within the range of 1500 to 2000 rpm. The second monitor the battery under the hood. The present invention eliminates the need for one operator. The lone operator can sit in the drivers seat and operate the gas pedal while monitoring the tachometer ang the invention voltage meter.

The cigarette lighter is directly connected to the battery and can provide a very accurate picture of the power thereof. Generally there are no accessories on the cigarette lighter's line as they would have interference when it was being operated.

This invention further contemplates incorporation of a tire gauge in the housing for measuring air pressure in the tires.

Obviously, numerous (additional) modifications and variations of the present invention are possible in light of the above teachings. It is, therefore, to be understood that within the scope of the appended claims, the invention may be practiced otherwise than as specifically described herein.

What is claimed is:

1. A voltage meter for measuring an automobile electrical system comprising a housing further comprising a protrusion for inserting into a power port, said power port further comprising conductive communication to a battery.

2. A voltage meter as set forth in claim 1 further comprising at least two conductive contacts disposed on said protrusion.

3. A voltage meter as set forth in claim 2 wherein said conductive contact is disposed on a terminus of said protrusion.

4. A voltage meter as set forth in claim 2 wherein said conductive contacts are located in order to contact counterparts in said power port.

5. A voltage meter as set forth in claim 4 wherein said power port comprises a cigarette lighter.

6. A voltage meter as set forth in claim 1 further comprising read out means.

7. A voltage meter as set forth in claim 6 wherein said read out means comprises an analog scale and indicator.

8. A voltage meter as set forth in claim 6 wherein said read out means comprises a digital display.

9. A voltage meter as set forth in claim 1 further comprising air pressure reading means.

10. A voltage meter as set forth in claim 1 further comprising air pressure read out means

11. A method of monitoring alternator output comprising the steps of running the alternator and simultaneously monitoring the voltage output of the electrical system.

12. A method as described in claim 11 wherein said steps are performed by a single operator.

13. A method as described in claim 11 further comprising a step of inserting a voltage monitor into contact with a cigarette lighter.
